(19) United States
(12) Patent Application Publication
(10) Pub. No.: US 2017/0170241 A1
(43) Pub. Date: Jun. 15, 2017

(54) DISPLAY PANEL

(71) Applicant: HON HAI PRECISION INDUSTRY CO., LTD., New Taipei (TW)

(72) Inventors: LI-CHIAO HUANG, New Taipei (TW); CHIA-YI TSAI, New Taipei (TW)

(21) Appl. No.: 15/444,468

(22) Filed: Feb. 28, 2017

Related U.S. Application Data
(62) Division of application No. 14/459,339, filed on Aug. 14, 2014, now abandoned.

(30) Foreign Application Priority Data
Aug. 14, 2013 (TW) 102129160

(51) Int. Cl. H01L 27/32; H01L 51/52; G02F 1/1335

(52) U.S. Cl. CPC H01L 27/322; G02F 1/133514; G02F 1/133512; H01L 51/5284; G02F 2001/133614; H01L 2251/5369

(57) ABSTRACT

A display panel includes a first substrate, a lighting device emitting a monochrome light, and a quantum dots layer. The display panel defines a plurality of pixel areas, each pixel area includes a plurality of sub-pixels for correspondingly emitting light of different colors. The quantum dots layer receives the monochrome light and converts the monochrome light to the light of different colors. The light passing through the quantum dots layer is directly emitted into the first sub-pixel, the second sub-pixel, and the third sub-pixel respectively.

### FIELD

The disclosure generally relates to display panel technologies.

### BACKGROUND

An organic light emitting diode (OLED) display panel usually employs different OLED material to emit light of three-primary colors. However, luminances of three-primary colors light emitted by the OLED material are different from each other. Luminance decay of each OLED material is also different from each other. Thus, color gamut of the OLED display panel is somehow compromised. In order to improve the color gamut of the OLED display panel, a number of circuits needs to be set on the OLED display panel to compensate the differences of luminances of three-primary colors light and luminance decay of different OLED material, which may increace complexity of the circuits and cost of the OLED display panel.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the views.

FIG. 1 is a diagrammatic view of a first embodiment of a display panel.

FIG. 2 is a cross-sectional view of the display panel of FIG. 1, taken along line II-II.

FIG. 3 is a cross-sectional view of a second embodiment of a display panel.

FIG. 4 is a cross-sectional view of a third embodiment of a display panel.

FIG. 5 is a cross-sectional view of a fourth embodiment of a display panel.

FIG. 6 is a cross-sectional view of a fifth embodiment of a display panel.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references can mean “at least one.”

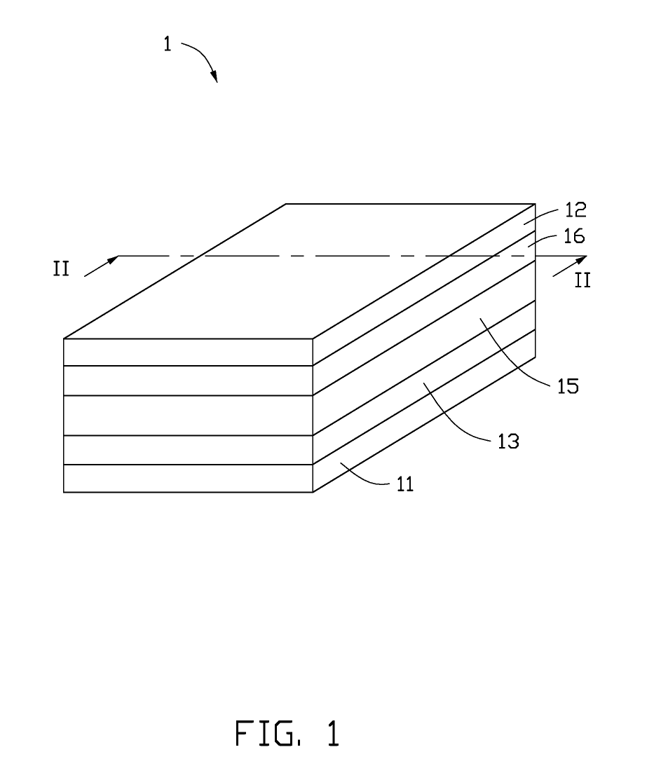

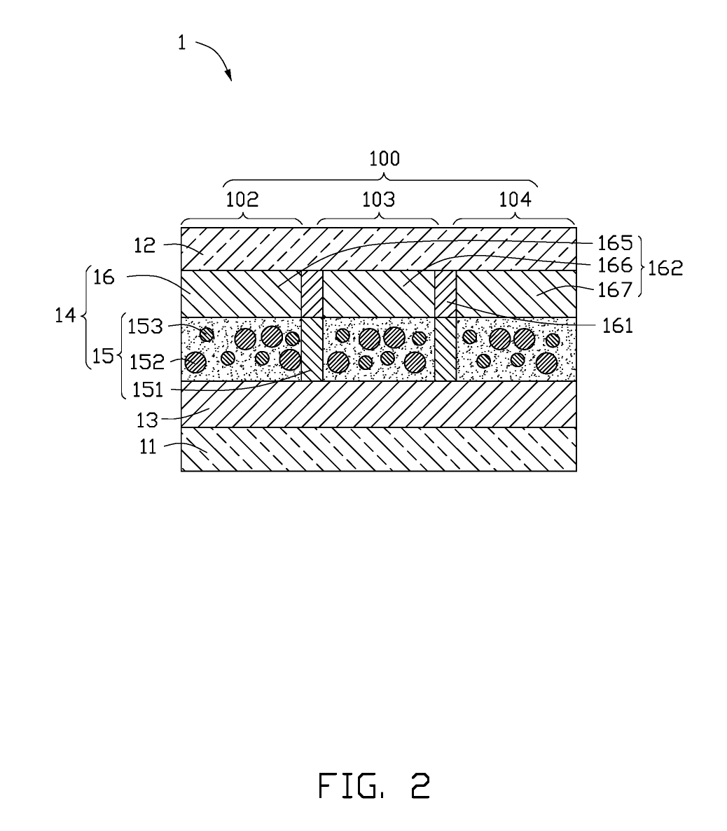

FIG. 1 illustrates a first embodiment of a display panel 1. FIG. 2 illustrates a cross-sectional view of the display panel 1 of FIG. 1, taken along line II-II. FIGS. 1 and 2 show one pixel area 100 for instance. The display panel 1 displays a full color image. The display panel 1 can be a liquid crystal display (LCD) panel or an OLED display panel. In this embodiment, the display panel 1 is an OLED display panel.

The display panel 1 includes a first substrate 11, a second substrate 12 opposite to the first substrate 11, a lighting device 13, and a color conversion layer 14. The display panel 1 defines a number of pixel areas 100. Each pixel area 100 includes a first sub-pixel 102, a second sub-pixel 103, and a third sub-pixel 104. The first sub-pixel 102, the second sub-pixel 103, and the third sub-pixel 104 respectively emit light with different colors. The lighting device 13 is formed on the first substrate 11 and configured for emitting a monochrome light. In this embodiment, the lighting device 13 is an OLED array substrate. The OLED array substrate includes a number of thin film transistors (not shown) to control the OLEDS corresponding to the sub-pixels 102, 103, and 104 to emit a blue light.

The color conversion layer 14 is set between the lighting device 13 and the second substrate 12. The color conversion layer 14 receives the blue light from the lighting device 13 and converts the bluelight to light of different colors. In this embodiment, the display panel 1 employs three-primary colors light to display the full color image. The first sub-pixel 102 emits a red light. The second sub-pixel 103 emits a green light. The third sub-pixel 104 emits a blue light.

The color conversion layer 14 includes a quantum dots layer 15 and a color filter 16. The quantum dots layer 15 is formed on the lighting device 13 to receive the light emitted by the lighting device 13. The color filter 16 is formed on a side of the quantum dots layer 15 opposite to the lighting device 13.

The quantum dots layer 15 includes a first black matrix 151, a number of red quantum dots 152, and a number of green quantum dots 153. The quantum dots layer 15 is divided into a number of units respectively corresponding to the first sub-pixel 102, the second sub-pixel 103, and the third sub-pixel 104 by the first black matrix 151. The red quantum dots 152 and the green quantum dots 153 are doped into each unit of the quantum dots layer 15. The red quantum dots 152 converts the light having a wavelength less than a wavelength of red light to the red light. The green quantum dots 153 converts the light having a wavelength less than a wavelength of green light to the green light. In this embodiment, the red quantum dots 152 converts the blue light to the red light. The green quantum dots 153 converts the blue light to the green light. Thus, the red light converted by the red quantum dots 152, the green light converted by the green quantum dots 153, and a remaining part of the blue light are mixed as a white light coming out of the quantum dots layer 15.

The color filter 16 includes a second black matrix 161 and a color layer 162. The color layer 162 is divided into a number of red filters 165, a number of green filters 166, and a number of blue filters 167 respectively corresponding to the first sub-pixels 102, the second sub-pixels 103, and the third sub-pixels 104. The red filters 165, the green filters 166, and the blue filters 167 are also aligned with the units of the quantum dots layer 15. The red filter 165 emits the red light by filtering the green light and the blue light of the white light coming out from the quantum dots layer 15. The green filter 166 emits the green light by filtering the red light and the blue light of the white light coming out from the quantum dots layer 15. The blue filter 167 emits the blue light by filtering the red light and the green light of the white light coming out from the quantum dots layer 15.

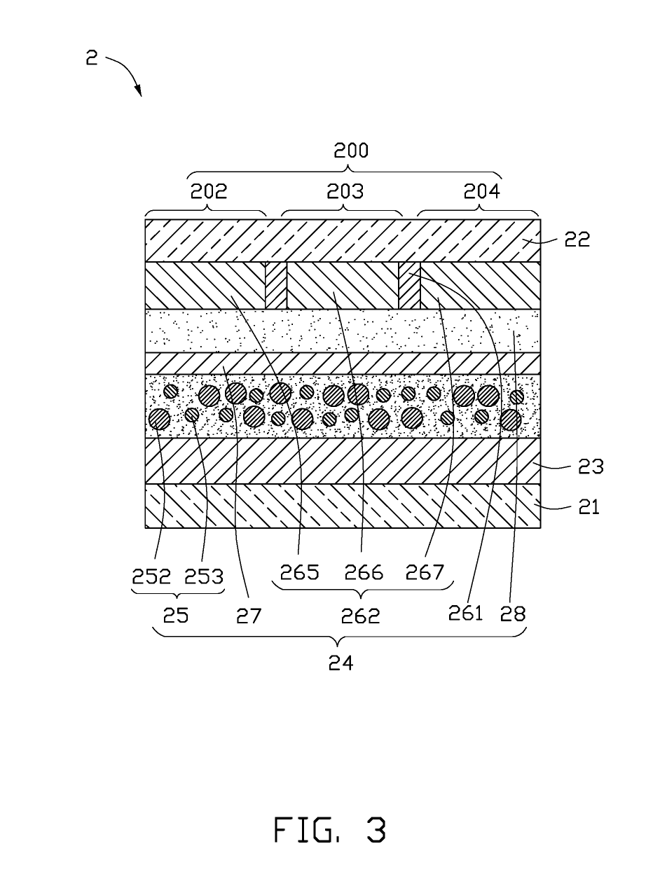

FIG. 3 illustrates a cross-sectional view of a second embodiment of a display panel 2. In this embodiment, the display panel 2 is an OLED display panel. The display panel 2 includes a first substrate 21, a second substrate 22 opposite to the first substrate 21, a lighting device 23, and a color conversion layer 24. The display panel 2 defines a number of pixel areas 200. FIG. 2 shows one pixel area 200 for instance. Each pixel area 200 includes a first sub-pixel 202, a second sub-pixel 203, and a third sub-pixel 204. The first sub-pixel 202, the second sub-pixel 203, and the third sub-pixel 204 respectively emit light of different colors. The lighting device 23 is formed on the first substrate 21 and configured for emitting a monochrome light. In this embodiment, the lighting device 23 is an OLED array substrate. The OLED array substrate includes a number of thin film transistors (not shown) to control the OLEDS corresponding to the sub-pixels 202, 203, and 204 to emit a blue light.

The color conversion layer 24 is set between the lighting device 23 and the second substrate 22. The color conversion layer 24 receives the blue light from the lighting device 23 and converts the blue light to light of different colors. In this embodiment, the display panel 2 employs three-primary colors light to display the full color image. The first sub-pixel 202 emits a red light. The second sub-pixel 203 emits a green light. The third sub-pixel 204 emits a blue light.

The color conversion layer 24 includes a quantum dots layer 25, a prism layer 27, and a color filter 26. The quantum dots layer 25 is formed on the lighting device 23 to receive the light emitted by the lighting device 23. The color filter 26 is formed on a side of the quantum dots layer 25 opposite to the lighting device 23. The prism layer 27 is set between the quantum dots layer 26 and the color filter 26. The prism layer 27 is sticked to the color filter 26 via an optical adhensive 28.

The quantum dots layer 25 includes a number of red quantum dots 252 and a number of green quantum dots 253. The red quantum dots 252 and the green quantum dots 253 are dispersed in the quantum dots layer 25. The red quantum dots 252 converts the light having a wavelength less than a wavelength of red light to the red light. The green quantum dots 253 converts the light having a wavelength less than a wavelength of green light to the green light. In this embodiment, the red quantum dots 252 converts the blue light to the red light. The green quantum dots 253 converts the blue light to the green light. Thus, the red light converted by the red quantum dots 252, the green light converted by the green quantum dots 253, and a remaining part of the blue light are mixed as a white light coming out of the quantum dots layer 25.

The prism layer 27 collimates the light coming out from the quantum dots layer 25 to make the light incident to the color filter 26 go along an approximately same direction.

The color filter 26 includes a black matrix 261 and a color layer 262. The color layer 262 is divided into a number of red filters 265, a number of green filters 266, and a number of blue filters 267 respectively corresponding to the first sub-pixels 202, the second sub-pixels 203, and the third sub-pixels 204 by the black matrix 261. The red filter 265 emits the red light by filtering the green light and the blue light of the white light coming out from the prism layer 27. The green filter 266 emits the green light by filtering the red light and the blue light of the white light coming out from the prism layer 27. The blue filter 267 emits the blue light by filtering the red light and the green light of the white light coming out from the prism layer 27.

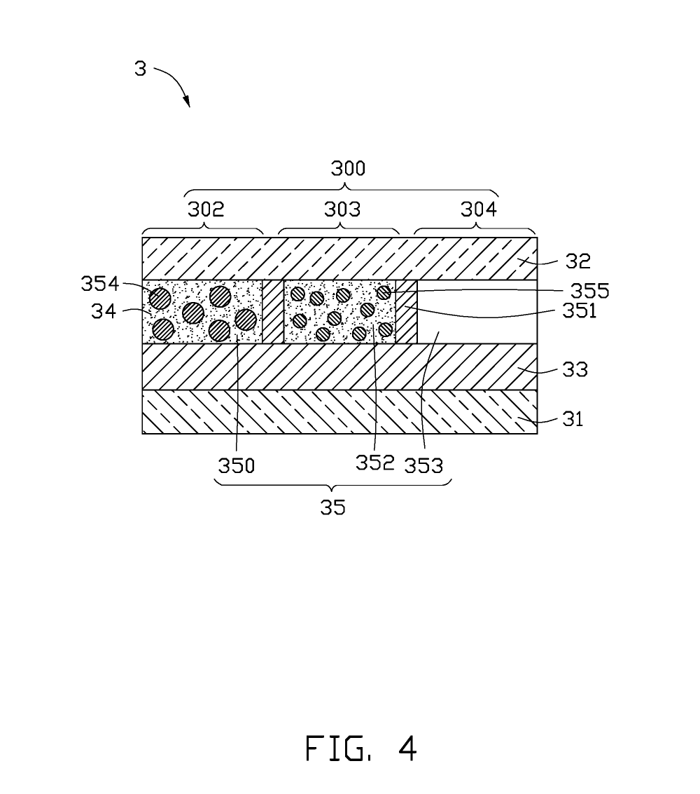

FIG. 4 illustrates a cross-sectional view of a third embodiment of a display panel 3. In this embodiment, the display panel 3 is an OLED display panel. The display panel 3 includes a first substrate 31, a second substrate 32 opposite to the first substrate 31, a lighting device 33, and a color conversion layer 34. The display panel 3 defines a number of pixel areas 300. FIG. 3 shows one pixel area 300 for instance. Each pixel area 300 includes a first sub-pixel 302, a second sub-pixel 303, and a third sub-pixel 304. The first sub-pixel 302, the second sub-pixel 303, and the third sub-pixel 304 respectively emit light with different colors. The lighting device 33 is formed on the first substrate 31 and configured for emitting a monochrome light. In this embodiment, the lighting device 33 is an OLED array substrate. The OLED array substrate includes a number of thin film transistors (not shown) to control the OLEDS corresponding to the sub-pixels 302, 303, and 304 to emit a blue light.

The color conversion layer 34 is set between the lighting device 33 and the second substrate 32. The color conversion layer 34 receives the blue light from the lighting device 33 and converts the blue light to light of different colors. In this embodiment, the display panel 3 employs three-primary colors light to display the full color image. The first sub-pixel 302 emits a red light. The second sub-pixel 303 emits a green light. The third sub-pixel 304 emits a blue light.

The color conversion layer 34 includes a quantum dots layer 35 and a black matrix 351. The quantum dots layer 35 is divided into a number of first areas 350, a number of second areas 352, and a number of third areas 353 respectively corresponding to the first sub-pixels 302, the second sub-pixels 303, and the third sub-pixels 304 by the black matrix 351. The quantum dots layers 35 includes a number of red quantum dots 354 and a number of green quantum dots 355. The red quantum dots 354 are dispersed in the first areas 350. The green quantum dots 355 are dispersed in the second areas 352. The third areas 353 are transparent areas without any quantum dots. The red quantum dots 352 converts the light having a wavelength less than a wavelength of red light to the red light. The green quantum dots 353 converts the light having a wavelength less than a wavelength of green light to the green light. In this embodiment, the red quantum dots 352 converts the blue light to the red light coming out from the first sub-pixel 302. The green quantum dots 353 converts the blue light to the green light coming out from the second sub-pixel 303. The blue light of the lighting device 33 passes through the transparent third areas 354 and comes out from the third sub-pixel 304.

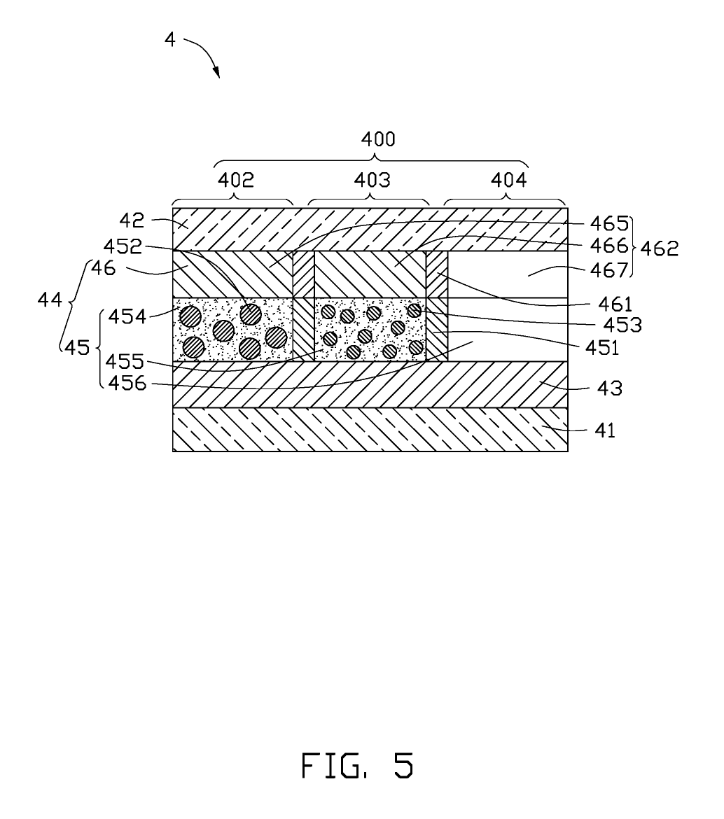

FIG. 5 illustrates a cross-sectional view of a fourth embodiment of a display panel 4. In this embodiment, the display panel 4 is an OLED display panel. The display panel 4 includes a first substrate 41, a second substrate 42 opposite to the first substrate 41, a lighting device 43, and a color conversion layer 44. The display panel 4 defines a number of pixel areas 400. FIG. 4 shows one pixel area 400 for instance. Each pixel area 400 includes a first sub-pixel 402, a second sub-pixel 403, and a third sub-pixel 404. The first sub-pixel 402, the second sub-pixel 403, and the third sub-pixel 404 respectively emit light with different colors. The lighting device 43 is formed on the first substrate 41 and configured for emitting a monochrome light. In this embodiment, the lighting device 43 is an OLED array substrate. The OLED array substrate includes a number of thin film transistors (not shown) to control the OLEDS corresponding to the sub-pixels 402, 403, and 404 to emit a blue light.

The color conversion layer 44 is set between the lighting device 43 and the second substrate 42. The color conversion layer 44 receives the blue light from the lighting device 43 and converts the blue light to light of different colors. In this embodiment, the display panel 4 employs three-primary colors light to display the full color image. The first sub-pixel 402 emits a red light. The second sub-pixel 403 emits a green light. The third sub-pixel 404 emits a blue light.

The color conversion layer 44 includes a quantum dots layer 45 and a color filter 46. The quantum dots layer 45 is formed on the lighting device 43 to receive the light emitted by the lighting device 43. The color filter 46 is formed on a side of the quantum dots layer 45 opposite to the lighting device 43.

The quantum dots layer 45 includes a first black matrix 451, a number of red quantum dots 452, and a number of green quantum dots 453. The quantum dots layer 45 is divided into a number of first units 454, a number of second units 455, and a number of third units 456 respectively corresponding to the first sub-pixels 402, the second sub-pixels 403, and the third sub-pixels 403 by the first black matrix 451. The red quantum dots 452 are dispersed in the first units 454. The green quantum dots 453 are dispersed in the second areas 455. The third units 456 are transparent units without any quantum dots. The red quantum dots 452 converts the light having a wavelength less than a wavelength of red light to the red light. The green quantum dots 453 converts the light having a wavelength less than a wavelength of green light to the green light. In this embodiment, the red quantum dots 452 converts the blue light to the red light coming out from the first units 454. The green quantum dots 453 converts the blue light to the green light coming out from the second units 455. The blue light passes through the transparent third units 456 and comes out from the third units 456.

The color filter 46 includes a second black matrix 461 and a color layer 462. The color layer 462 is divided into a number of red filters 465, a number of green filters 466, and a number of transparent portions 467 respectively corresponding to the first sub-pixels 402, the second sub-pixels 403, and the third sub-pixels 404 by the second black matrix 461. The red filters 465, the green filters 466, and the transparent portions 467 are also correspondingly aligned with the first units 454, the second units 455, and the third units 456 of the quantum dots layer 45. The red filter 465 emits the red light by filtering the remaining blue light coming out from the first unit 454. The green filter 466 emits the green light by filtering the remaining blue light coming out from the second unit 455. The blue light coming out from the transparent third unit 456 passes through the transparent portion 467 as the blue light.

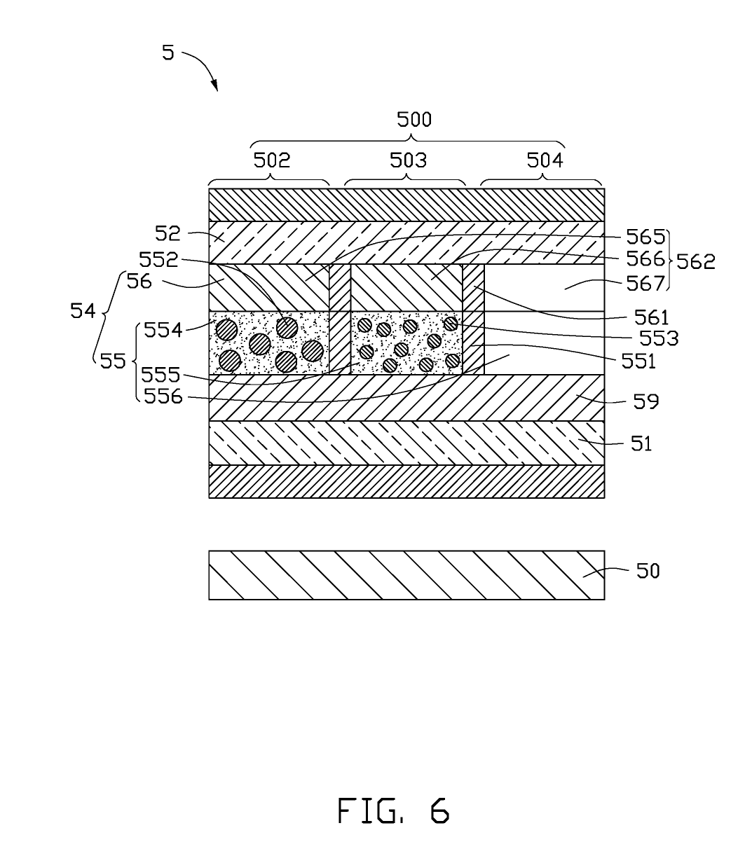

FIG. 6 illustrate a cross-sectional view of a fifth embodiment of a display panel 5. In this embodiment, the display panel 5 is a LCD display panel. The display panel 5 includes a light module 50, a first substrate 51, a second subsrate 52, a liquid crystal layer 59 set between the first substrate 51 and the second substrate 52, and a color conversion layer 54 set between the liquid crystal layer 59 and the second substrate 52. The light module 50 is set at a side of the first substrate 51 opposite to the second substrate 52 and configured for emitting a monochrome light. In this embodiment, the light module 50 is a light emitting diode (LED) emitting a blue light. The first substrate 51 is an array substrate.

The display panel 5 defines a number of pixel areas 500. FIG. 5 shows one pixel area 500 for instance. Each pixel area 500 includes a first sub-pixel 502, a second sub-pixel 503, and a third sub-pixel 504. The first sub-pixel 502, the second sub-pixel 503, and the third sub-pixel 504 respectively emit light with different colors.

The color conversion layer 54 receives the blue light from the light module 50 and converts the blue light to light of different colors. In this embodiment, the display panel 5 employs three-primary colors light to display the full color image. The first sub-pixel 502 emits a red light. The second sub-pixel 503 emits a green light. The third sub-pixel 504 emits a blue light.

The color conversion layer 54 includes a quantum dots layer 55 and a color filter 56. The color filter 56 is formed on the second substrate 52. The quantum dots layer 55 is formed on a surface of the color filter 56 opposite to the second substrate 52 to receive the blue light passing through the first substrate 51 and the liquid crystal layer 59.

The quantum dots layer 55 includes a first black matrix 551, a number of red quantum dots 552, and a number of green quantum dots 553. The quantum dots layer 55 is divided into a number of first units 554, a number of second units 555, and a number of third units 556 respectively corresponding to the first sub-pixels 502, the second sub-pixels 503, and the third sub-pixels 503 by the first black matrix 551. The red quantum dots 552 are dispersed in the first units 554. The green quantum dots 553 are dispersed in the second areas 555. The third units 556 are transparent units without any quantum dots. The red quantum dots 552 converts the light having a wavelength less than a wavelength of red light to the red light. The green quantum dots 553 converts the light having a wavelength less than a wavelength of green light to the green light. In this embodiment, the red quantum dots 552 converts the blue light to the red light coming out from the first units 554. The green quantum dots 553 converts the blue light to the green light coming out from the second units 555. The blue light passes through the transparent third units 556 and comes out from the third units 556.

The color filter 56 includes a second black matrix 561 and a color layer 562. The color layer 562 is divided into a number of red filters 565, a number of green filters 566, and a number of transparent portions 567 respectively corresponding to the first sub-pixels 502, the second sub-pixels 503, and the third sub-pixels 504 by the second black matrix 561. The red filters 565, the green filters 566, and the transparent portions 567 are also correspondingly aligned with the first units 554, the second units 555, and the third units 556 of the quantum dots layer 55. The red filter 565 emits the red light by filtering the remaining blue light coming out from the first unit 554. The green filter 566 emits the green light by filtering the remaining blue light coming out from the second unit 555. The blue light coming out from the transparent third unit 556 passes through the transparent portion 567 as the blue light.

It is believed that the present embodiments and their advantages will be understood from the foregoing description, and it will be apparent that various changes may be made thereto without departing from the scope of the disclosure or sacrificing all of its material advantages.

What is claimed is:

1. A display panel defining a plurality of pixel areas, each pixel area comprising a first sub-pixel, a second sub-pixel, and a third sub-pixel, the display panel comprising:
a lighting device configured to emit a monochrome light; and
a quantum dots layer;
wherein the quantum dots layer receives the monochrome light and emits a first light for the first sub-pixel, a second light for the second sub-pixel, and a third light for the third sub-pixel, each of the first light, the second light, and the third light is a monochrome light and has a different color from each other; the light passing through the quantum dots layer is directly emitted into the first sub-pixel, the second sub-pixel, and the third sub-pixel respectively.

2. The display panel of claim 1, wherein the lighting device emits a blue light; the quantum dots layer comprises a plurality of red quantum dots and a plurality of green quantum dots, the red quantum dots converts the blue light to a red light, the green quantum dots converts the blue light to a green light, and the red light converted by the red quantum dots, the green light converted by the green quantum dots, and a remaining part of the blue light are mixed as a white light coming out of the color conversion layer.

3. The display panel of claim 2, wherein the display panel employs three-primary colors light to display the full color image, the first sub-pixel emits a red light, the second sub-pixel emits a green light, and the third sub-pixel emitting a blue light.

4. The display panel of claim 1, further comprising a first substrate and a second substrate facing away from the first substrate, wherein the lighting device is located on a surface of the first substrate, and the quantum dots layer further is located on a surface of the second substrate substrate facing the first substrate, the light from the quantum dots layer passing through the second substrate is directly emitted into the first sub-pixel, the second sub-pixel, and the third sub-pixel respectively.

5. The display panel of claim 1, wherein the lighting device comprises an organic light emitting diode (OLED) array substrate with a plurality of OLEDs and a number of thin film transistors corresponding to the OLEDs; each of the OLEDs faces the quantum dots layer and corresponds to one of the first, second, and third sub-pixel; the thin film transistors control the corresponding OLEDs to emit a blue light respectively.

6. The display panel of claim 1, wherein the lighting device emits a blue light, the display panel employs three-primary colors light to display the full color image, the first sub-pixel emitting a red light, the second sub-pixel emitting a green light, and the third sub-pixel emitting a blue light, the quantum dotsf layer is divided into a plurality of first areas corresponding to the first sub-pixel, a plurality of second areas corresponding to the second sub-pixel, and a plurality of third areas corresponding to the third sub-pixel by a first black matrix.

7. The display panel of claim 6, wherein the quantum dots layer comprises a plurality of red quantum dots dispersed in the first areas and a plurality of green quantum dots dispersed in the second areas, the red quantum dots converts the blue light to a red light, the green quantum dots converts the blue light to a green light, the third areas is a transparent area, the red light converted by the red quantum dots comes out from the first sub-pixel, the green light converted by the green quantum dots comes out from the second sub-pixel, and the blue light pass through the transparent third area and comes out from the third sub-pixel.

8. A display panel defining a plurality of pixel areas, each pixel area comprising a first sub-pixel and a second sub-pixel, the display panel comprising:
a first substrate;
a second substrate facing away from the first substrate;
a lighting device located on a surface of the first substrate, and configured to emit a monochrome light; and
a quantum dots layer located on a surface of the lighting device facing away from the first substrate, and comprising a quantum dots layer;
wherein the quantum dots layer is located on a surface of the second substrate facing the first substrate; the quantum dots layer receives the monochrome light and emits a first light for the first sub-pixel and a second light for the second sub-pixel, the first light has a color different from the second light.

9. The display panel of claim 8, wherein the light from the quantum dots layer passing through the second substrate is directly emitted into the first sub-pixel, the second sub-pixel, and the third sub-pixel respectively.

10. The display panel of claim 8, wherein the lighting device emits a blue light; the quantum dots layer comprises a plurality of red quantum dots and a plurality of green quantum dots, the red quantum dots converts the blue light to a red light, the green quantum dots converts the blue light to a green light, and the red light converted by the red quantum dots, the green light converted by the green quantum dots, and a remaining part of the blue light are mixed as a white light coming out of the quantum dots layer.

11. The display panel of claim 8, wherein the lighting device comprises an organic light emitting diode (OLED) array substrate with a plurality of OLEDs and a number of thin film transistors corresponding to the OLEDs; each of the OLEDs faces the quantum dots layer and corresponds to one of the first, second, and third sub-pixel; the thin film transistors control the corresponding OLEDs to emit a blue light respectively.

12. The display panel of claim 8, wherein the lighting device emits a blue light, the display panel employs three-primary colors light to display the full color image, the first sub-pixel emitting a red light, the second sub-pixel emitting a green light, and the third sub-pixel emitting a blue light, the quantum dots layer is divided into a plurality of first areas corresponding to the first sub-pixel, a plurality of second areas corresponding to the second sub-pixel, and a plurality of third areas corresponding to the third sub-pixel by a first black matrix.

13. The display panel of claim 12, wherein the quantum dots layer comprises a plurality of red quantum dots dispersed in the first areas and a plurality of green quantum dots dispersed in the second areas, the red quantum dots converts the blue light to a red light, the green quantum dots converts the blue light to a green light, the third areas is a transparent area, the red light converted by the red quantum dots comes out from the first sub-pixel, the green light converted by the green quantum dots comes out from the second sub-pixel, and the blue light pass through the transparent third area and comes out from the third sub-pixel.

14. The display panel of claim 8, wherein the lighting device emits a blue light, the display panel employs three-primary colors light to display the full color image, the first sub-pixel emitting a red light, the second sub-pixel emitting a green light, and the third sub-pixel emitting a blue light, the quantum dotsf layer is divided into a plurality of first areas corresponding to the first sub-pixel, a plurality of second areas corresponding to the second sub-pixel, and a plurality of third areas corresponding to the third sub-pixel by a first black matrix.
